(19) United States
(12) Patent Application Publication
(10) Pub. No.: US 2023/0056222 A1
(43) Pub. Date: Feb. 23, 2023

(54) SEMICONDUCTOR PACKAGES

(71) Applicant: SK hynix Inc., Icheon-si Gyeonggi-do (KR)

(72) Inventors: Kang Hun KIM, Icheon-si Gyeonggi-do (KR); Si Yun KIM, Icheon-si Gyeonggi-do (KR); Jun Yong SONG, Icheon-si Gyeonggi-do (KR)

(73) Assignee: SK hynix Inc., Icheon-si Gyeonggi-do (KR)

(21) Appl. No.: 17/577,196

(22) Filed: Jan. 17, 2022

(30) Foreign Application Priority Data
Aug. 18, 2021 (KR) 10-2021-0109085

(51) Int. Cl. H01L 23/498; H01L 23/00

(52) U.S. Cl. CPC H01L 23/49838; H01L 24/17; H01L 23/49822; H01L 23/49827; H01L 24/06; H01L 24/16; H01L 2224/0612; H01L 2224/1712; H01L 2224/16227; H01L 2224/48227; H01L 24/48

(57) ABSTRACT

A semiconductor package may be presented. The semiconductor package includes a first dielectric layer including a first surface and a second surface. First and second conductive lands are disposed on the first surface of the first dielectric layer. A first column formed by the first conductive lands and a second column formed by the second conductive lands are spaced apart from each other. Outer traces extend from the second conductive lands, and inner traces are disposed on the second surface of the first dielectric layer. Vias penetrate the first dielectric layer and respectively connect the first conductive lands to the inner traces. A semiconductor die is disposed on the first surface of the first dielectric layer.

### CROSS-REFERENCE TO RELATED APPLICATIONS

The present application claims priority under 35 U.S.C. 119(a) to Korean Applications No. 10-2021-0109085, filed on Aug. 18, 2021, which is incorporated herein by reference in its entirety.

### BACKGROUND

### 1. Technical Field

The present disclosure relates to a semiconductor packaging technology, and more particularly, to a semiconductor package including an interconnection.

### 2. Related Art

A semiconductor package may include a semiconductor die and a packaging substrate. Integrated circuits (ICs) may be integrated into the semiconductor die. The semiconductor die may be mounted on the packaging substrate. The semiconductor package may include an encapsulant layer that protects the semiconductor die.

The semiconductor die and the packaging substrate may be electrically connected to each other by a bump interconnection. The bump interconnection may refer to a structure in which a connection pad of a semiconductor die and a bump land of the packaging substrate are connected to each other through a conductive bump. The bump land may refer to a portion of a conductive trace of the packaging substrate or a portion of a conductive lead of the packaging substrate. The conductive bump may refer to a shape of a solder ball, a metal bump, a metal post, or a conductive pillar.

As semiconductor packaging technology develops, there is an increasing demand for reducing the size of a semiconductor die. In addition, as the semiconductor die is required to realize high density and high performance, the number of connection pads or the number of bumps or the number of bump lands required for the semiconductor die is also increasing. Attempts are being made to secure wider spacing between bump lands, between conductive bumps, or between connection pads while configuring a required number of connection pads within a limited area of a semiconductor die.

### SUMMARY

In an embodiment of the present disclosure, a semiconductor package may include a first dielectric layer including a first surface and a second surface; first conductive lands disposed on the first surface of the first dielectric layer and forming a first column; second conductive lands disposed on the first surface of the first dielectric layer and forming a second column spaced apart from the first column; outer traces extending from the second conductive lands; inner traces disposed on the second surface of the first dielectric layer; vias penetrating the first dielectric layer and connecting the first conductive lands to the inner traces; and a semiconductor die disposed on the first surface of the first dielectric layer.

In an embodiment of the present disclosure, a semiconductor package may include a first dielectric layer including a first surface and a second surface; first conductive lands disposed on the first surface of the first dielectric layer; second conductive lands disposed on the first surface of the first dielectric layer; outer traces extending from the second conductive lands; inner traces disposed on the second surface of the first dielectric layer; vias penetrating the first dielectric layer and connecting the first conductive lands to the inner traces; and a semiconductor die disposed on the first surface of the first dielectric layer and including first die pads respectively connected to the first conductive lands and second die pads respectively connected to the second conductive lands, wherein the first die pads are disposed on the semiconductor die while forming a zigzag arrangement with the second die pads.

In an embodiment of the present disclosure, a semiconductor package may include a first dielectric layer including a first surface and a second surface; first conductive lands disposed on the first surface of the first dielectric layer and forming a first column; second conductive lands disposed on the first surface of the first dielectric layer and forming a second column spaced apart from the first column; outer traces extending from the second conductive lands; inner traces disposed on the second surface of the first dielectric layer; vias penetrating the first dielectric layer and connecting the first conductive lands to the inner traces; a semiconductor die disposed on the first surface of the first dielectric layer; and bonding wires connecting the semiconductor die to the first and second conductive lands.

### BRIEF DESCRIPTION OF THE DRAWINGS

FIGS. 1 and 2 are schematic cross-sectional views illustrating a semiconductor package according to an embodiment of the present disclosure.

FIG. 3 is a schematic plan view illustrating an arrangement shape in which conductive lands of the semiconductor package of FIGS. 1 and 2 are disposed.

FIG. 4 is a schematic plan view illustrating an arrangement shape in which traces of the semiconductor package of FIGS. 1 and 2 are disposed.

FIG. 5 is a schematic plan view illustrating an arrangement shape in which die pads of the semiconductor package of FIGS. 1 and 2 are disposed.

FIG. 6 is a schematic plan view illustrating an arrangement shape in which connection bumps and conductive lands of the semiconductor package of FIGS. 1 and 2 are disposed.

FIG. 7 is a schematic plan view illustrating an arrangement shape in which connection bumps and conductive lands are disposed according to a comparative example.

FIGS. 8 and 9 are schematic cross-sectional views illustrating a semiconductor package according to another embodiment of the present disclosure.

FIG. 10 is a schematic plan view illustrating an arrangement shape in which conductive lands and traces of the semiconductor package of FIGS. 8 and 9 are disposed,

FIG. 11 is a schematic plan view illustrating an arrangement shape in which die pads of the semiconductor package of FIGS. 8 and 9 are disposed.

FIG. 12 is a block diagram illustrating an electronic system employing a memory card including a package according to an embodiment of the present disclosure.

FIG. 13 is a block diagram illustrating an electronic system including a package according to an embodiment of the present disclosure.

### DETAILED DESCRIPTION

The terms used in the description of the embodiments of the present disclosure are terms selected in consideration of functions in the presented embodiments, and the meaning of the terms may vary according to the intention or custom of users or operators in the technical field. The meanings of the terms used are in accordance with the defined definitions when specifically defined in the present disclosure, if there is no specific definition, it may be interpreted as the meaning generally recognized by those skilled in the art.

In the description of the embodiments of the present disclosure, descriptions such as “first,” “second,” “side,” “top” and “bottom or lower” are to distinguish subsidiary materials, not used to limit the subsidiary materials themselves or to imply any particular order. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout.

The semiconductor device may include a semiconductor substrate or a structure in which plurality of semiconductor substrates are stacked. The semiconductor device may indicate a semiconductor package structure in which a structure in which semiconductor substrates are stacked is packaged. Semiconductor substrates may refer to semiconductor wafers, semiconductor dies or semiconductor chips on which electronic components and elements are integrated. The semiconductor chip may refer to a memory chip in which a memory integrated circuit such as DRAM, SRAM, NAND FLASH, NOR FLASH, MRAM, ReRAM, FeRAM, FeRAM, or PcRAM is integrated, or a logic die in which a logic circuit is integrated on a semiconductor substrate or a processor such as an ASIC chip, an application processor (AP), a graphic processing unit (GPU), a central processing unit (CPU), or a system on a chip (SoC). The semiconductor device may be applied to information communication devices such as portable terminals, bio or health care related electronic devices, and wearable electronic devices. The semiconductor device may be applied to the Internet of Things.

The same reference numerals may refer to the same elements throughout the present disclosure. The same reference numerals or similar reference numerals may be described with reference to other drawings, even if they are not mentioned or described in the corresponding drawings. Further, even if a reference numeral is not indicated, it may be described with reference to other drawings.

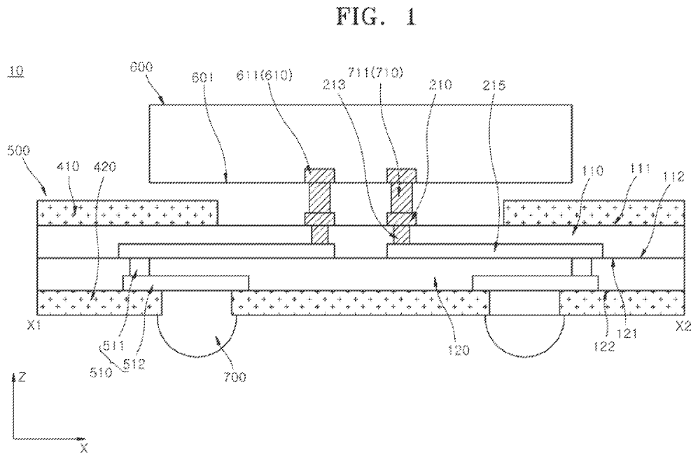

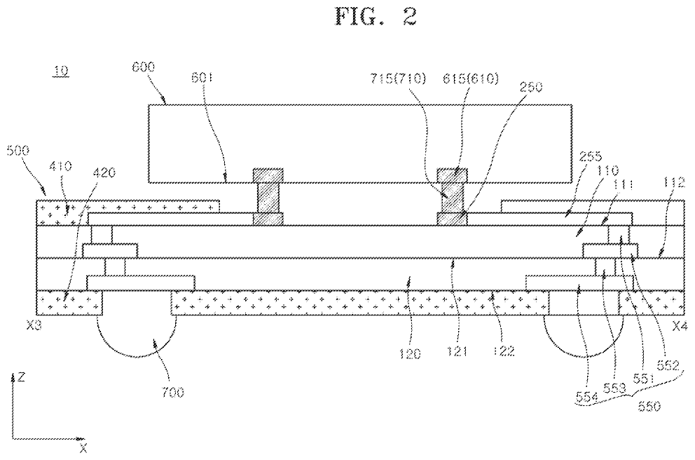

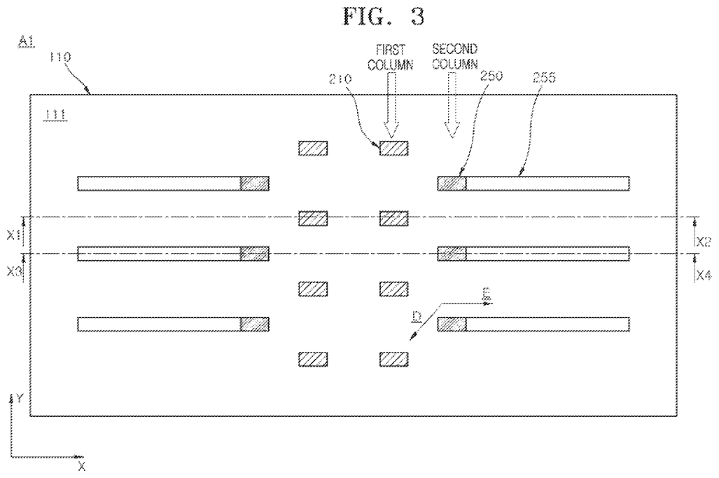

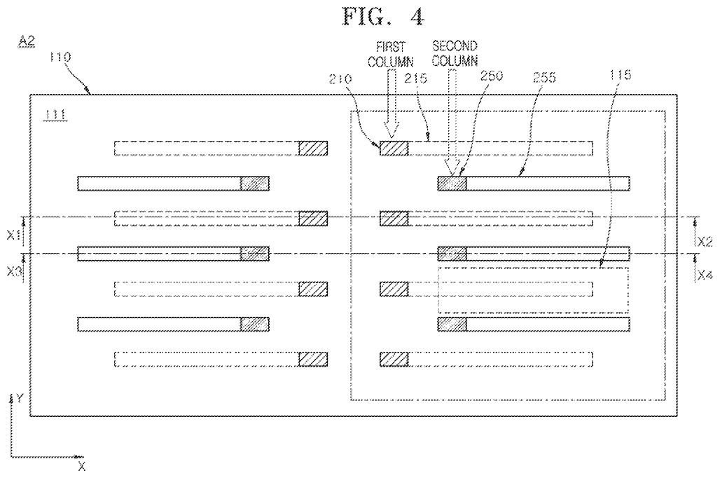

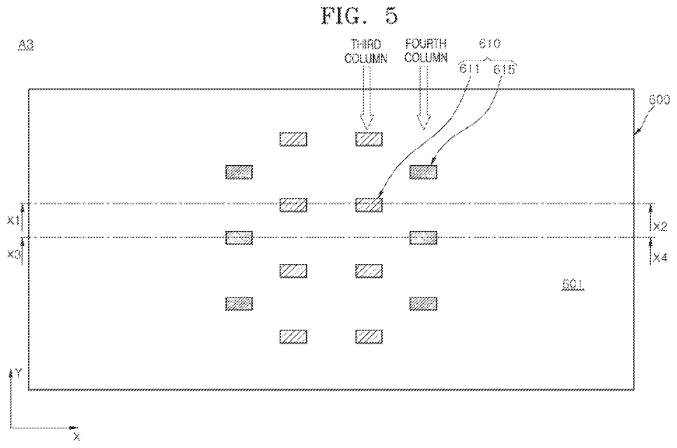

FIGS. 1 and 2 are schematic cross-sectional views illustrating a semiconductor package 10 according to an embodiment of the present disclosure. FIG. 3 is a schematic plan view illustrating an arrangement shape A1 in which conductive lands 210 and 250 of the semiconductor package 10 of FIGS. 1 and 2 are disposed, FIG. 4 is a schematic plan view illustrating an arrangement shape A2 in which traces 215 and 255 of the semiconductor package 10 of FIGS. 1 and 2 are disposed. FIG. 5 is a schematic plan view illustrating an arrangement shape A3 in which die pads 610 of the semiconductor package 10 of FIGS. 1 and 2 are disposed. FIG. 1 illustrates a schematic X-Z cross-sectional shape of the semiconductor package 10 along the cutting line X1-X2 of FIGS. 4 and 5, FIG. 2 illustrates a schematic X-Z cross-sectional shape of the semiconductor package 10 along the cutting line X3-X4 of FIGS. 4 and 5.

Referring to FIG. 1, the semiconductor package 10 may include a semiconductor die 600 and a packaging substrate 500. The semiconductor die 600 may include a device in which integrated circuits (ICs) are integrated. The semiconductor die 600 may include a device in which memory devices such as DRAM or NAND are integrated. The semiconductor die 600 may be disposed on the packaging substrate 500.

The packaging substrate 500 may include an interconnection component that electrically connects the semiconductor die 600 to an external device, an external module, or an external component. In an example, the packaging substrate 500 may be configured in a form of a printed circuit board (PCB). In an example, the packaging substrate 500 may be formed in a structural element including a dielectric layer and conductive patterns disposed in the dielectric layer. The conductive patterns may indicate redistribution layers (RDL).

Although not illustrated, the semiconductor package 10 may further include an encapsulant layer covering and protecting the semiconductor die 600. The encapsulant layer may include various encapsulation materials. In an example, the encapsulant layer may be formed by a molding process of molding an epoxy molding compound (EMC).

The packaging substrate 500 may include a first dielectric layer 110. The packaging substrate 500 may further include a second dielectric layer 120 supporting the first dielectric layer 110. The first dielectric layer 110 and the second dielectric layer 120 may be layers constituting a body of the packaging substrate 500 or constituting a core layer of the packaging substrate 500. The first dielectric layer 110 and the second dielectric layer 120 may include various dielectric materials. Each of the first dielectric layer 110 and the second dielectric layer 120 may include an epoxy resin or a polymer layer. The first dielectric layer 110 may include a first surface 111 and a second surface 112 opposite to each other. The second dielectric layer 120 may be formed on the second surface 112 of the first dielectric layer 110. The second dielectric layer 120 may be laminated to the first dielectric layer 110.

The semiconductor package 10 may include a connection structure that electrically connects the semiconductor die 600 to the packaging substrate 500. The connection structure may include a first connection structure including first conductive lands 210, first die pads 611, and first connection bumps 711. Each of the first conductive lands 210 may include a bump land to which the first connection bump 711 is connected. The first die pad 611 may be a portion of die pads 610 provided in the semiconductor die 600. The die pads 610 may be connection terminals that electrically connect the integrated circuits (ICs) integrated in the semiconductor die 600 to an external device. The first connection bump 711 may be a portion of the connection bumps 710.

The semiconductor die 600 may be disposed on the first surface 111 of the first dielectric layer 110 such that a surface 601 of the semiconductor die 600 faces the first surface 111 of the first dielectric layer 110. The first conductive lands 210 may be disposed on the first surface 111 of the first dielectric layer 110. The first conductive lands 210 may be disposed at positions overlapping with the first die pads 611 of the semiconductor die 600. The first connection bumps 711 may be positioned between the first conductive lands 210 and the first die pads 611, and may connect the first die pads 611 to the first conductive lands 210.

Referring to FIG. 2, the connection structure for electrically connecting the semiconductor die 600 to the packaging substrate 500 may include a second connection structure including second conductive lands 250, second die pads 615, and second connection bumps 715. Each of the second conductive lands 250 may include a bump land to which the second connection bump 715 is connected. Each of the second die pads 615 may be a portion of the die pads 610 provided in the semiconductor die 600. Each of the second connection bumps 715 may be a portion of the connection bumps 710. The second conductive lands 250 may be disposed on the first surface 111 of the first dielectric layer 110. The second conductive lands 250 may be disposed at positions overlapping with the second die pads 615 of the semiconductor die 600. The second connection bumps 715 may be positioned between the second conductive lands 250 and the second die pads 615, and may connect the second die pads 615 to the second conductive lands 250.

The connection bumps 710 may be bonded to the first conductive lands 210 and the second conductive lands 250 to electrically connect the semiconductor die 600 to the first and second conductive lands 210 and 250, respectively. Each of the connection bumps 710 may include a solder layer for bonding. The solder layer may be a conductive adhesive layer by which the connection bumps 710 are substantially bonded to the first and the second conductive lands 210 and 250.

Referring to FIGS. 3 and 1, the plurality of first conductive lands 210 may be disposed on the first surface 111 of the first dielectric layer 110 in a first column. The first conductive lands 210 may be arranged in the first column in the Y-axis direction on the X-Y plane. The plurality of second conductive lands 250 may be disposed on the first surface 111 of the first dielectric layer 110 in a second column. The second column of the second conductive lands 250 may be spaced apart from the first column of the first conductive lands 210. The second column of the second conductive lands 250 may be spaced apart from the first column of the first conductive lands 210 in the X-axis direction.

Referring to FIG. 3, the first conductive lands 210 may form a zigzag arrangement with the second conductive lands 250. The first conductive lands 210 may be disposed to be spaced apart from the second conductive lands 250 in a diagonal direction D on the first surface 111 of the first dielectric layer 110. The diagonal direction D may be a direction between the X-axis direction and the Y-axis direction. The diagonal direction D may be a direction having a certain angle from the X-axis direction and the Y-axis direction. For example, in an embodiment, the first conductive lands 210 may form a zigzag arrangement with the second conductive lands 250 as shown in FIG. 3. In FIG. 3, for example, the first conductive lands 210 are alternately arranged and spaced apart in the diagonal direction D with the second conductive lands 250 to form a zigzag arrangement. In an embodiment, the first conductive lands 210 are disposed to be spaced apart from the second conductive lands 250 in a diagonal direction D with respect to a direction in which the outer traces extend 255.

Referring to FIGS. 3 and 1, each of the first conductive lands 210 may be a conductive pattern having an island shape. Each of the first conductive lands 210 may include a metal material such as copper (Cu). On the first surface 111 of the first dielectric layer 110, because other conductive patterns are not substantially connected to the first conductive lands 210 and do not substantially extend from the first conductive lands 210, each of the first conductive lands 210 may be an isolated conductive pattern in an island shape.

Referring to FIGS. 3 and 2, first outer traces 255 may extend from the second conductive lands 250. The first outer traces 255 may be disposed on the first surface 111 of the first dielectric layer 110. Each of the first outer trace 255 and the second conductive land 250 may be formed in a conductive pattern composed of a single body. Each of the first outer trace 255 and the second conductive land 250 may be formed of a conductive pattern including copper.

Referring to FIG. 3, the first outer traces 255 may extend in a direction away from the second conductive lands 250. The first outer traces 255 may extend alongside each other. The first outer traces 255 may extend in the X-axis direction. The first outer traces 255 may extend in a direction away from the first conductive lands 210 while being connected to the second conductive lands 250 one by one. Each of the first conductive lands 210 may be disposed to be spaced apart from the second conductive lands 250 in the diagonal direction D with respect to a direction E in which the first outer traces 255 extend. Accordingly, the first conductive lands 210 may form a zigzag arrangement or a staggered arrangement with the second conductive lands 250.

Referring to FIGS. 1 and 4, inner traces 215 may be disposed on the second surface 112 of the first dielectric layer 110. As illustrated in FIG. 4, because the first outer traces 255 and the first conductive lands 210 are disposed on the first surface 111 of the first dielectric layer 110, the inner traces 215 may be disposed on a different layer from the first conductive lands 210 and the first outer traces 255. The inner traces 215 may be formed in conductive patterns electrically connected to the first conductive lands 210.

Referring to FIG. 1, because the inner traces 215 are disposed on a different layer from the first conductive lands 210, conductive first vias 213 may connect the inner traces 215 to the first conductive lands 210. Because the inner traces 215 are disposed on the second surface 112 of the first dielectric layer 110 and the first conductive lands 210 are disposed on the first surface 111 of the first dielectric layer 110, the conductive first vias 213 may each have a shape penetrating the first dielectric layer 110 to connect the inner traces 215 to the first conductive lands 210. The conductive first vias 213 may penetrate the first dielectric layer 110 substantially vertically. The first conductive lands 210 may be disposed on the first surface 111 of the first dielectric layer 110 to overlap with the conductive first vias 213.

Referring to FIGS. 4 and 1, the inner traces 215 may extend in a direction away from the conductive first vias 213 and the first conductive lands 210. The inner traces 215 may extend alongside each other. The inner traces 215 may extend in the X-axis direction. The inner traces 215 may extend in a direction away from the first conductive lands 210 while being connected to the conductive first vias 213 one by one. As illustrated in FIG. 4, the inner traces 215 may extend to partially overlap with regions 115 located between the first outer traces 255 and located between the second conductive lands 250. The inner traces 215 are located on a different layer from the first outer traces 255 and the second conductive lands 250, so that there may be no restriction on positions in which the inner traces 215 are disposed. Some of the inner traces 215 may overlap with the first outer traces 255 or the second conductive lands 250.

Referring again to FIG. 1, a first solder resist layer 410 may be further disposed on the first surface 111 of the first dielectric layer 110. The first solder resist layer 410 may be formed in a dielectric layer pattern exposing the first conductive lands 210 to which the first connection bumps 711 are bonded. The semiconductor package 10 may further include outer connectors 700 formed on the second dielectric layer 120. The outer connectors 700 may be connection terminals electrically connecting the semiconductor package 10 to an external device.

Some of the outer connectors 700 may be electrically connected to the inner traces 215. Some of the outer connectors 700 may be electrically connected to the semiconductor die 600 through the inner traces 215, the conductive first vias 213, the first conductive lands 210, the first connection bumps 711, and the first die pads 611.

A first interconnection structure 510 electrically connecting some of the outer connectors 700 to the inner traces 215 may be disposed in the second dielectric layer 120. The second dielectric layer 120 may have a third surface 121 and a fourth surface 122 opposite to each other. The third surface 121 of the second dielectric layer 120 may be a surface in contact with the second surface 112 of the first dielectric layer 110. The first interconnection structure 510 may include a second via 511 and a second outer trace 512. The second outer trace 512 may be disposed on the fourth surface 122 that is an outer surface of the second dielectric layer 120 opposite to the first dielectric layer 110. The second via 511 may penetrate the second dielectric layer 120 substantially vertically and may electrically connect the second outer trace 512 and the inner traces 215 to each other. A second solder resist layer 420 may be disposed on the fourth surface 122 of the second dielectric layer 120 while exposing a portion of the second outer trace 512. The outer connectors 700 may be formed on or attached to a portion of the second outer trace 512 exposed by the second solder resist layer 420. The outer connectors 700 may be formed as connecting members such as conductive bumps or solder balls.

Referring again to FIG. 2, the first solder resist layer 410 may be formed in a dielectric layer pattern further exposing the second conductive lands 250 to which the second connection bumps 715 are bonded. Some of the outer connectors 700 may be electrically connected to the first outer traces 255. Some other of the connectors 700 may be electrically connected to the semiconductor die 600 through the first outer traces 255, the second conductive lands 250, the second connection bumps 715, and the second die pads 615.

Second interconnection structures 550 electrically connecting some other of the outer connectors 700 and the first outer traces 255 to each other may be disposed in the first and second dielectric layers 110 and 120. Each of the second interconnection structures 550 may include a third via 551, a via land 552, a fourth via 553, and a third outer trace 554. The third outer traces 554 may be disposed on the fourth surface 122 of the second dielectric layer 120 while being positioned on substantially the same layer as the second outer traces 512 of FIG. 1. The fourth vias 553 may penetrate the second dielectric layer 120 substantially vertically, and may electrically connect the via lands 552 and the third outer traces 554 to each other. The third vias 551 may penetrate the first dielectric layer 110 substantially vertically, and may electrically connect the via lands 552 and the first outer traces 255 to each other. The via lands 552 may be disposed on substantially the same layer as the inner traces 215. The via lands 552 may be disposed on the second surface 112 of the first dielectric layer 110 to electrically connect the third vias 551 and the fourth vias 553 to each other. The second solder resist layer 420 may be disposed in a dielectric layer pattern further exposing portions of the third outer traces 554. Some other of the outer connectors 700 may be formed on or attached to portions of the third outer traces 554 exposed by the second solder resist layer 420.

Referring to FIG. 5, the semiconductor die 600 may include the first die pads 611 and the second die pads 615 arranged in different columns. The plurality of first die pads 611 may be disposed in a third column on the surface 601 of the semiconductor die 600. The plurality of second die pads 615 may be disposed in a fourth column on the surface 601 of the semiconductor die 600. The fourth column of the second die pads 615 may be spaced apart from the third column of the first die pads 611. The fourth column of the second die pads 615 may be spaced apart from the third column of the first die pads 611 in the X-axis direction.

As illustrated in FIG. 1, the first die pads 611 may be connected to the first conductive lands 210 and may be positioned to overlap with the first conductive lands 210. As illustrated in FIG. 2, the second die pads 615 may be connected to the second conductive lands 250 and may be positioned to overlap with the second conductive lands 250. Accordingly, as the first conductive lands 210 illustrated in FIG. 4 form a zigzag arrangement with the second conductive lands 250, the first die pads 611 illustrated in FIG. 5 may be disposed in a zigzag arrangement with the second die pads 615.

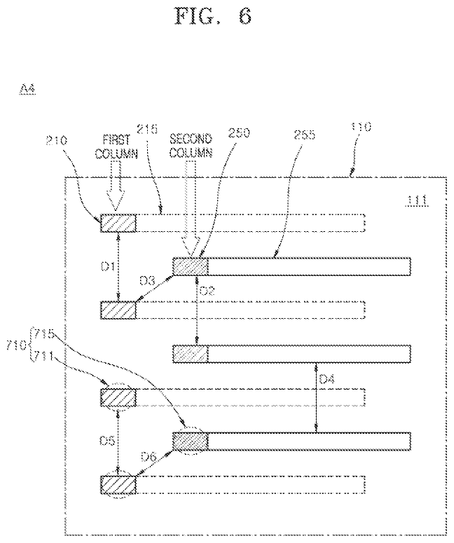

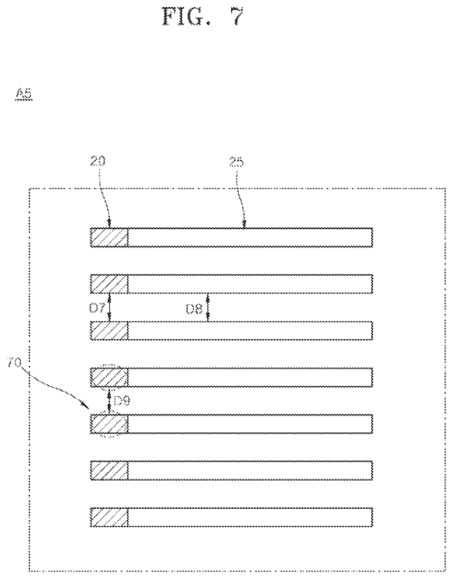

FIG. 6 is a schematic plan view illustrating an arrangement shape A4 in which the connection bumps 710 and the conductive lands 210 and 250 of the semiconductor package 10 of FIGS. 1 and 2 are disposed. FIG. 7 is a schematic plan view illustrating an arrangement shape A5 in which the connection bumps 70 and the conductive lands 20 are disposed according to a comparative example. FIG. 7 illustrates a comparative example in which conductive lands 20 are arranged in one column in a longitudinal direction.

As illustrated in FIG. 6, because the first conductive lands 210 and the second conductive lands 250 are disposed in a zigzag arrangement on the first surface 111 of the first dielectric layer 110, the first conductive lands 210 adjacent to each other may be disposed while securing a relatively wide spacing D1 than the spacing D7 of the conductive lands 20 illustrated in FIG. 7. Accordingly, the spacing D5 between each of the first connection bumps 711 that are respectively landed and bonded to the first conductive lands 210 adjacent to each other may be secured wider than the spacing D9 between each of the connection bumps 70 illustrated in FIG. 7. In an embodiment, because the spacing D5 between each of the first connection bumps 711 is secured relatively wide, a bridge fail in which the first connection bumps 711 are connected to each other or an electrical short risk may be reduced.

In FIG. 6, the second conductive lands 250 adjacent to each other may be disposed while securing a relatively wide spacing D2 than the spacing D7 of the conductive lands 20 illustrated in FIG. 7. Accordingly, the spacing between each of the second connection bumps 715 respectively bonded to the second conductive lands 250 adjacent to each other may also be secured to be wider than the spacing D9 of each of the connection bumps 70 illustrated in FIG. 7.

In FIG. 6, the first conductive land 210 and the second conductive land 250 adjacent to each other may also be disposed while securing a relatively wide spacing D3 than the spacing D7 of the conductive lands 20 illustrated in FIG. 7. Accordingly, the spacing D6 between the first and second connection bumps 711 and 715 adjacent to each other and bonded to the first and second conductive lands 210 and 250, respectively, may also be secured wider than the spacing D9 of the connection bumps 70 illustrated in FIG. 7. Accordingly, in an embodiment, the bridge fail in which the first and second connection bumps 711 and 715 are connected to each other or an electrical short risk may be reduced.

As illustrated in FIG. 6, because the inner traces 215 are disposed on a different layer from the first outer traces 255, the spacing D4 between each of the first outer traces 255 may be secured wider than the spacing D8 between each of the traces 25 illustrated in FIG. 7. Accordingly, in an embodiment, the bridge fail in which the second connection bump 715 is undesirably connected to the adjacent first outer trace 255 or an electrical short risk may be reduced. Furthermore, in an embodiment, because the inner traces 215 are not disposed on the first surface 111 of the first dielectric layer 110, but are disposed on the second surface 112 of FIG. 1, which is a different layer, a bridge fail in which the second connection bumps 715 are undesirably connected to the inner traces 215 may be fundamentally prevented or mitigated.

As such, some embodiments of the present disclosure may secure a relatively wide spacing between the conductive lands. In addition, some embodiments of the present disclosure may secure a relatively wide spacing between the conductive land and the traces. Accordingly, in some embodiments, it is possible to reduce undesirable connection of the connection bump bonded to a conductive land to adjacent connection bump or another conductive land or trace. In addition, in some embodiments, it is possible to reduce bridge fail between conductive lands or between conductive lands and traces due to migration of copper (Cu) constituting the conductive lands and traces.

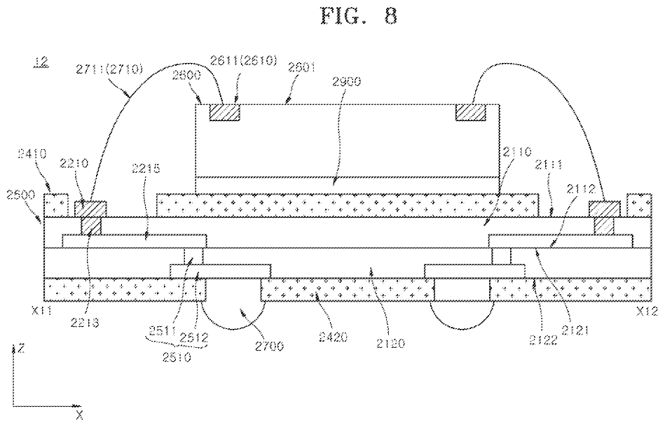

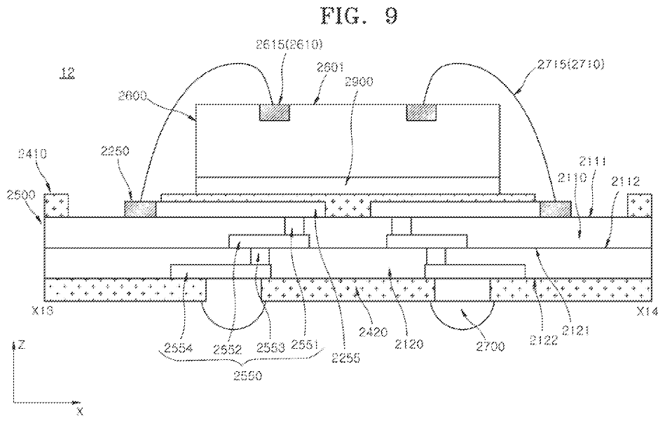

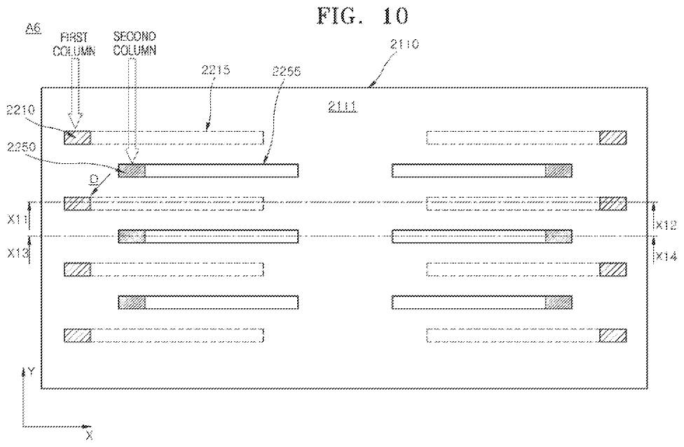

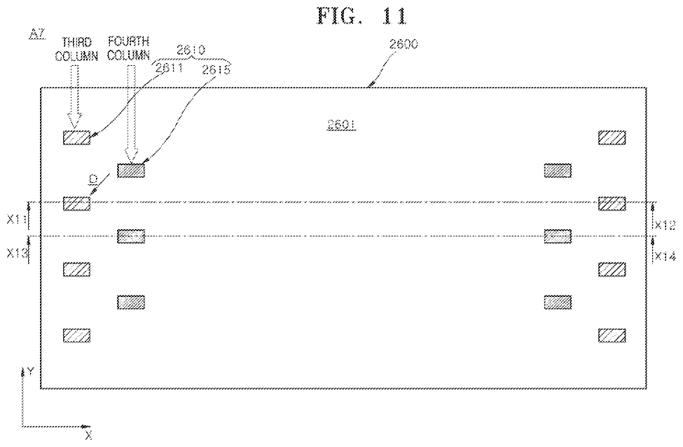

FIGS. 8 and 9 are schematic cross-sectional views illustrating a semiconductor package 12 according to another embodiment of the present disclosure. FIG. 10 is a schematic plan view illustrating an arrangement shape A6 in which conductive lands 2210 and 2250 and traces 2215 and 2255 of the semiconductor package 12 of FIGS. 8 and 9 are disposed. FIG. 11 is a schematic plan view illustrating an arrangement shape A7 in which die pads 2610 of the semiconductor package 12 of FIGS. 8 and 9 are disposed. FIG. 8 illustrates a schematic cross-sectional shape of the semiconductor package 12 along the cutting line X11-X12 of FIGS. 10 and 11. FIG. 9 illustrates a schematic cross-sectional shape of the semiconductor package 12 along the cutting line X13-X14 of FIGS. 10 and 11. As indicated in the FIGS. 8 and 10, in an embodiment, the first conductive lands 2210 are disposed on the first surface 2111 of the first dielectric layer 2110 to respectively align horizontally with the first die pads 2611 in the X direction. As indicated in the FIGS. 9 and 10, in an embodiment, the second conductive lands 2250 are disposed on the first surface 2111 of the first dielectric layer 2110 to respectively align horizontally with the second die pads 2615 in the X direction.

Referring to FIGS. 8 and 9, the semiconductor package 12 may include a semiconductor die 2600 and a packaging substrate 2500. The semiconductor die 2600 may be attached to the packaging substrate 2500 by an adhesive layer 2900. The packaging substrate 2500 may include a first dielectric layer 2110 and a second dielectric layer 2120. The first dielectric layer 2110 may include a first surface 2111 and a second surface 2112 opposite to each other. The second dielectric layer 2120 may be disposed on the second surface 2112 of the first dielectric layer 2110. The second dielectric layer 2120 may include a third surface 2121 and a fourth surface 2122 opposite to each other. The third surface 2121 of the second dielectric layer 2120 may be a surface in contact with the second surface 2112 of the first dielectric layer 2110.

Referring to FIG. 8, the semiconductor package 12 may include connection structures that electrically connect the semiconductor die 2600 to the packaging substrate 2500. Each of the connection structures may include a first conductive land 2210, a first die pad 2611, and a first bonding wire 2711. The first conductive land 2210 may include a bond finger to which the first bonding wire 2711 is coupled. The first die pad 2611 may be a portion of the die pads 2610 included in the semiconductor die 2600. The first bonding wire 2711 may be a portion of the bonding wires 2710.

The semiconductor die 2600 may be disposed on the first surface 2111 of the first dielectric layer 2110 such that a surface 2601 of the semiconductor die 2600 faces substantially the same direction as the first surface 2111 of the first dielectric layer 2110. The first conductive lands 2210 may be disposed on the first surface 2111 of the first dielectric layer 2110. The first conductive lands 2210 may be disposed at positions corresponding to the first die pads 2611 of the semiconductor die 2600. The first bonding wires 2711 may connect the first die pads 2611 to the first conductive lands 2210.

Referring to FIG. 9, each of the connection structures for electrically connecting the semiconductor die 2600 to the packaging substrate 2500 may include a second conductive land 2250, a second die pad 2615, and a second bonding wire 2715. The second conductive land 2250 may include a bond finger to which the second bonding wire 2715 is coupled. The second die pad 2615 may be a portion of the die pads 2610 included in the semiconductor die 2600. The second bonding wire 2715 may be a portion of the bonding wires 2710. The second conductive lands 2250 may be disposed on the first surface 2111 of the first dielectric layer 2110. The second bonding wires 2715 may connect the second die pads 2615 to the second conductive lands 2250.

Referring to FIGS. 10 and 8, the plurality of first conductive lands 2210 may be disposed on the first surface 2111 of the first dielectric layer 2110 in a first column. The plurality of second conductive lands 2250 may be disposed on the first surface 2111 of the first dielectric layer 2110 in a second column. The second column of the second conductive lands 2250 may be spaced apart from the first column of the first conductive lands 2210. The first conductive lands 2210 may form a zigzag arrangement with the second conductive lands 2250. Each of the first conductive lands 2210 may be a conductive pattern having an island shape. On the first surface 2111 of the first dielectric layer 2110, other conductive patterns are not substantially connected to the first conductive lands 2210 and do not substantially extend from the first conductive lands 2210, so that each of the first conductive lands 2210 may be an isolated conductive pattern in an island shape. In an embodiment, the first conductive lands 2210 are disposed to be spaced apart from the second conductive lands 2250 in a diagonal direction D with respect to a direction in which the outer traces extend 2255.

Referring to FIGS. 10 and 9, first outer traces 2255 may extend from the second conductive lands 2250. The first outer traces 2255 may be disposed on the first surface 2111 of the first dielectric layer 2110. The first outer trace 2255 and the second conductive land 2250 may be formed in a conductive pattern composed of a single body.

Referring to FIGS. 10 and 8, inner traces 2215 may be disposed on the second surface 2112 of the first dielectric layer 2110. Because the first outer traces 2255 and the first conductive lands 2210 are disposed on the first surface 2111 of the first dielectric layer 2110, the inner traces 2215 may be disposed on a different layer from the first conductive lands 2210 and the first outer traces 2255. The inner traces 2215 may be formed in conductive patterns electrically connected to the first conductive lands 2210.

The inner traces 2215 are disposed on a different layer from the first conductive lands 2210, so that the conductive first vias 2213 may connect the inner traces 2215 to the first conductive lands 2210. The conductive first vias 2213 may have shapes penetrating the first dielectric layer 2110, so that the conductive first vias 2213 may connect the inner traces 2215 to the first conductive lands 2210. The conductive first vias 2213 may penetrate the first dielectric layer 2110 substantially vertically. The first conductive lands 2210 may be disposed on the first surface 2111 of the first dielectric layer 2110 to overlap with the conductive first vias 2213.

Referring to FIG. 8, a first solder resist layer 2410 may be further formed on the first surface 2111 of the first dielectric layer 2110. The first solder resist layer 2410 may be formed in a dielectric layer pattern exposing the first conductive lands 2210. The semiconductor package 12 may further include outer connectors 2700 formed on the second dielectric layer 2120. Some of the outer connectors 2700 may be electrically connected to the inner traces 2215. Some of the outer connectors 2700 may be electrically connected to the semiconductor die 2600 through the inner traces 2215, the conductive first vias 2213, the first conductive lands 2210, the first bonding wires 2711, and the first die pads 2611.

First interconnection structures 2510 electrically connecting some of the outer connectors 2700 to the inner traces 2215 may be formed in the second dielectric layer 2120. The first interconnection structures 2510 may include second vias 2511 and second outer traces 2512. The second outer traces 2512 may be disposed on the fourth surface 2122 that is an outer surface of the second dielectric layer 2120. The second vias 2511 may penetrate the second dielectric layer 2120 substantially vertically and may electrically connect the second outer traces 2512 and the inner traces 2215 to each other. A second solder resist layer 2420 may be formed on the fourth surface 2122 of the second dielectric layer 2120 while exposing a portion of the second outer trace 2512. The outer connectors 2700 may be formed on or attached to a portion of the second outer trace 2512 exposed by the second solder resist layer 2420.

Referring to FIG. 9, the first solder resist layer 2410 may be formed in a dielectric layer pattern that further exposes the second conductive lands 2250 to which the second bonding wires 2715 are bonded. Some other of the outer connectors 2700 may be electrically connected to the first outer traces 2255. Some other of the outer connectors 2700 may be electrically connected to the semiconductor die 2600 through the first outer traces 2255, the second conductive lands 2250, the second bonding wires 2715, and the second die pads 2615.

Second interconnection structures 2550 that electrically connect some other of the outer connectors 2700 to the first outer traces 2255 may be formed in the first and second dielectric layers 2110 and 2120. The second interconnection structures 2550 may include third vias 2551, via lands 2552, fourth vias 2553, and third outer traces 2554. The third outer traces 2554 may be disposed on the fourth surface 2122 of the second dielectric layer 2120 while being positioned on substantially the same layer as the second outer traces 2512 of FIG. 8. The fourth vias 2553 may penetrate the second dielectric layer 2120 substantially vertically, and may electrically connect the via lands 2552 and the third outer traces 2554 to each other. The third vias 2551 may penetrate the first dielectric layer 2110 substantially vertically, and may electrically connect the via lands 2552 and the first outer traces 2255 to each other. The via lands 2552 may be disposed on substantially the same layer as inner traces 2215. The via lands 2552 may be disposed on the second surface 2112 of the first dielectric layer 2110 to electrically connect the third vias 2551 and the fourth vias 2553. The second solder resist layer 2420 may be formed in a dielectric layer pattern further exposing a portion of the third outer trace 2554. Some other of the outer connectors 2700 may be formed on or attached to the third outer trace 2554 exposed by the second solder resist layer 2420.

Referring to FIG. 11, a semiconductor die 2600 may include first die pads 2611 and second die pads 2615 which are arranged in different columns. The plurality of first die pads 2611 may be disposed in a third column on a surface 2601 of the semiconductor die 2600. The plurality of second die pads 2615 may be disposed in a fourth column on the surface 2601 of the semiconductor die 2600. The fourth column of the second die pads 2615 may be spaced apart from the third column of the first die pads 2611. The fourth column of the second die pads 2615 may be spaced apart from the third column of the first die pads 2611 in the X-axis direction. The first die pads 2611 may be disposed in a zigzag arrangement with the second die pads 2615. For example, in an embodiment, the first die pads 2611 may form a zigzag arrangement with the second die pads 2615 as shown in FIG. 11. In FIG. 11, for example, the first die pads 2611 are alternately arranged and spaced apart in the diagonal direction D with the second die pads 2615 to form a zigzag arrangement. For example, in an embodiment, the first conductive lands 2210 may form a zigzag arrangement with the second conductive lands 2250 as shown in FIG. 10. In FIG. 10, for example, the first conductive lands 2210 are alternately arranged and spaced apart in the diagonal direction D with the second conductive lands 2250 to form a zigzag arrangement.

As such, some of the embodiments of the present disclosure may secure a relatively wide spacing between each of the conductive lands. In addition, some of the embodiments of the present disclosure may secure a relatively wide spacing between the conductive lands and the traces. Accordingly, in an embodiment, it is possible to reduce the undesirable connection of a connection bump bonded to a conductive land to adjacent connection bump, or another conductive land or trace.

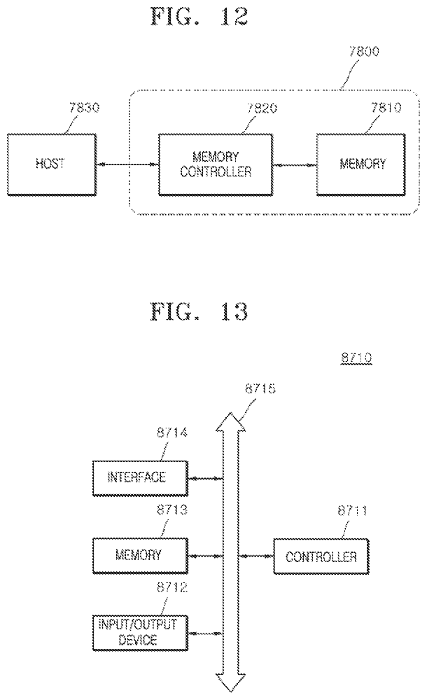

FIG. 12 is a block diagram illustrating an electronic system including a memory card 7800 employing at least one of the semiconductor packages according to the embodiments of the present disclosure. The memory card 7800 includes a memory 7810 such as a nonvolatile memory device, and a memory controller 7820. The memory 7810 and the memory controller 7820 may store data or read out the stored data. At least one of the memory 7810 and the memory controller 7820 may include at least one of the semiconductor packages according to the embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

FIG. 13 is a block diagram illustrating an electronic system 8710 including at least one of the semiconductor packages according to the embodiments of the present disclosure. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include at least one of the semiconductor packages according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or Wibro (wireless broadband Internet).

Various concepts have been disclosed in conjunction with various embodiments as described above. Accordingly, the embodiments disclosed in the present specification should be considered from not a restrictive standpoint but an illustrative standpoint. The scope of the embodiments should not be limited to the above descriptions.

What is claimed is:

1. A semiconductor package comprising:
a first dielectric layer including a first surface and a second surface;
first conductive lands disposed on the first surface of the first dielectric layer and forming a first column;
second conductive lands disposed on the first surface of the first dielectric layer and forming a second column spaced apart from the first column;
outer traces extending from the second conductive lands;
inner traces disposed on the second surface of the first dielectric layer;
vias penetrating the first dielectric layer and connecting the first conductive lands to the inner traces; and
a semiconductor die disposed on the first surface of the first dielectric layer.

2. The semiconductor package of claim 1, wherein the first conductive lands include island-shaped conductive patterns.

3. The semiconductor package of claim 1, wherein the first conductive lands are disposed on the first surface of the first dielectric layer while forming a zigzag arrangement with the second conductive lands.

4. The semiconductor package of claim 1, wherein the first conductive lands are disposed to be spaced apart from the second conductive lands in a diagonal direction with respect to a direction in which the outer traces extend.

5. The semiconductor package of claim 1, wherein the first conductive lands are disposed on the first surface of the first dielectric layer to overlap with the vias.

6. The semiconductor package of claim 1, wherein the vias penetrate substantially vertically the first dielectric layer.

7. The semiconductor package of claim 1, wherein the outer traces extend substantially parallel to one another.

8. The semiconductor package of claim 1, wherein the inner traces extend to partially overlap with a region located between the outer traces and a region located between the second conductive lands.

9. The semiconductor package of claim 1, further comprising:
a second dielectric layer formed on the second surface of the first dielectric layer; and
outer connectors formed on the second dielectric layer and electrically connected to the inner traces and the outer traces.

10. The semiconductor package of claim 1, further comprising connection bumps electrically connecting the semiconductor die to the first conductive lands and the second conductive lands and bonded to the first conductive lands and the second conductive lands.

11. A semiconductor package comprising:
a first dielectric layer including a first surface and a second surface;
first conductive lands disposed on the first surface of the first dielectric layer;
second conductive lands disposed on the first surface of the first dielectric layer;
outer traces extending from the second conductive lands;
inner traces disposed on the second surface of the first dielectric layer;
vias penetrating the first dielectric layer and connecting the first conductive lands to the inner traces; and
a semiconductor die disposed on the first surface of the first dielectric layer and including first die pads respectively connected to the first conductive lands and second die pads respectively connected to the second conductive lands,
wherein the first die pads are disposed on the semiconductor the while forming a zigzag arrangement with the second die pads.

12. The semiconductor package of claim 11,
wherein the first conductive lands are disposed on the first surface of the first dielectric layer to respectively overlap with the first the pads, and
wherein the second conductive lands are disposed on the first surface of the first dielectric layer to respectively overlap with the second die pads.

13. The semiconductor package of claim 11, wherein the first conductive lands include island-shaped conductive patterns.

14. The semiconductor package of claim 11, wherein the first conductive lands are disposed to be spaced apart from the second conductive land in a diagonal direction with respect to a direction in which the outer traces extend.

15. The semiconductor package of claim 11, wherein the first conductive lands are disposed on the first surface of the first dielectric layer to respectively overlap with the vias.

16. The semiconductor package of claim 11, wherein the vias penetrate substantially vertically the first dielectric layer.

17. The semiconductor package of claim 11, wherein the outer traces extend substantially parallel to one another.

18. The semiconductor package of claim 11, wherein the inner traces extend to partially overlap with a region located between the outer traces and a region located between the second conductive lands.

19. The semiconductor package of claim 11, further comprising:
a second dielectric layer formed on the second surface of the first dielectric layer; and
outer connectors formed on the second dielectric layer and electrically connected to the inner traces and the outer traces.

20. The semiconductor package of claim 1, further comprising:
connection bumps bonding the first and second die pads to the first and second conductive lands of the semiconductor die, respectively.

21. A semiconductor package comprising:
a first dielectric layer including a first surface and a second surface;
first conductive lands disposed on the first surface of the first dielectric layer and forming a first column;
second conductive lands disposed on the first surface of the first dielectric layer and forming a second column spaced apart from the first column;
outer traces extending from the second conductive lands;
inner traces disposed on the second surface of the first dielectric layer;
vias penetrating the first dielectric layer and connecting the first conductive lands to the inner traces;
a semiconductor die disposed on the first surface of the first dielectric layer; and
bonding wires connecting the semiconductor die to the first and second conductive lands.

22. The semiconductor package of claim 21, wherein the first conductive lands are disposed on the first surface of the first dielectric layer while forming a zigzag arrangement with the second conductive lands.

23. The semiconductor package of claim 21,
wherein the semiconductor die includes:
first the pads respectively corresponding to the first conductive lands; and
second die pads respectively corresponding to the second conductive lands, and
wherein the first the pads are disposed on a surface of the semiconductor die while forming a zigzag arrangement with the second die pads.

24. The semiconductor package of claim 21, further comprising outer traces extending from the second conductive lands and disposed on the first surface of the first dielectric layer.

25. The semiconductor package of claim 21,
wherein the first conductive lands align horizontally with the first die pads, respectively, and
wherein the second conductive lands align horizontally with the second die pads, respectively.
